(19) United States
(12) Patent Application Publication
(10) Pub. No.: US 2019/0221680 A1
(43) Pub. Date: Jul. 18, 2019

(54) SOLAR CELL MODULE INCLUDING TERMINAL BOX AND METHOD OF MANUFACTURING SOLAR CELL

(71) Applicant: Panasonic Intellectual Property Management Co., Ltd., Osaka (JP)

(72) Inventors: Toshiyuki SAKUMA, Osaka (JP); Ryoji NAITO, Fukuoka (JP); Kengo MATSUNE, Osaka (JP); Masaki SHIMA, Kyoto (JP); Hiroyuki KANNOU, Osaka (JP)

(21) Appl. No.: 16/368,343

(22) Filed: Mar. 28, 2019

Related U.S. Application Data
(63) Continuation of application No. PCT/JP2017/034756, filed on Sep. 26, 2017.

(30) Foreign Application Priority Data
Sep. 29, 2016 (JP) 2016-191990

(51) Int. Cl. H01L 31/02; H02S 40/34; H01L 31/18; H01L 31/05

(52) U.S. Cl. CPC H01L 31/02013; H01L 31/0504; H01L 31/18; H02S 40/34

(57) ABSTRACT

A second protective member has a slit for exposing a lead wiring member from a solar cell panel. A terminal box is connected to the lead wiring member from the slit in the second protective member. A bonding member bonds the terminal box and the second protective member. A peripheral portion around the slit in the second protective member projects farther than a non-peripheral portion other than the peripheral portion. The bonding member is provided in the non-peripheral portion in the second protective member.

### CROSS-REFERENCE TO RELATED APPLICATION

This application is based upon and claims the benefit of priority from the prior Japanese Patent Application No. 2016-191990, filed on Sep. 29, 2016, the entire contents of which are incorporated herein by reference.

### BACKGROUND

### 1. Field

The disclosure relates to a solar cell module and, more particularly, to a solar cell module including a terminal box.

### 2. Description

A plurality of solar cell devices are electrically connected in series by wiring members. The wiring members are electrically connected to each other by connection members. By connecting the wiring members to a terminal box provided on the back surface of the solar cell module, electric power generated is extracted outside (see, for example, JP2006-19440).

A silicone adhesive is used to attach a terminal box on the back surface side of a solar cell panel. A double-sided adhesive tape is also used to temporarily attach the terminal box until the silicone adhesive is solidified. The thickness of the double-sided adhesive tape may cause the terminal box attached to become shaky. Shakiness of the terminal box may induce a stress in the silicone adhesive with the result that the terminal box may be displaced from the position where it is intended to be attached.

### SUMMARY

The present disclosure addresses the issue discussed above and a purpose thereof is to inhibit the shakiness of a terminal box attached.

A solar cell module according to an embodiment of the disclosure includes: a back surface protective member having a slit for exposing a lead wiring member from a solar cell panel; a terminal box connected to the lead wiring member from the slit in the back surface protective member; and a bonding member that bonds the terminal box and the back surface protective member. A peripheral portion around the slit in the back surface protective member projects farther than a non-peripheral portion other than the peripheral portion, and the bonding member is provided in the non-peripheral portion in the back surface protective member.

Another embodiment of the disclosure relates to a method of manufacturing a solar cell module. The method includes: attaching a bonding member to a back surface protective member having a slit for exposing a lead wiring member from a solar cell panel or to a terminal box; and bonding the terminal box to the back surface protective member by the bonding member, wherein a peripheral portion around the slit in the back surface protective member projects farther than a non-peripheral portion other than the peripheral portion, and the bonding member is provided in the non-peripheral portion in the back surface protective member.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a plan view of a solar cell module according to the embodiment as viewed from the back surface side;

FIGS. 2A-2B are enlarged plan views of a portion of the solar cell panel of FIG. 1;

FIG. 3 is a cross sectional view of the solar cell module of FIG. 1;

FIG. 4 is a plan view of another solar cell module according to the embodiment as viewed from the back surface side;

FIG. 5 is an enlarged plan view of a portion of the solar cell panel of FIG. 4;

FIG. 6 is a plan view of the second protective member of FIG. 3 as viewed from the back surface side;

FIGS. 7A-7B show a structure of a terminal box attached to the solar cell module of FIG. 1; and

FIG. 8A-8B show a structure of the solar cell module in which the terminal box of FIGS. 7A-7B is attached.

### DETAILED DESCRIPTION

The invention will now be described by reference to the preferred embodiments. This does not intend to limit the scope of the present invention, but to exemplify the invention.

A brief summary will be given before describing the disclosure in specific details. An embodiment relates to a solar cell module in which a terminal box is provided on the back surface side of the solar cell panel. A lead wiring member is guided from the back surface side of the solar cell panel. By connecting the lead wiring member to the terminal box, electric power generated in the solar cell panel is output outside. The lead wiring member is provided to overlap the solar cell within the solar cell panel. The arrangement may bring the lead wiring member to be in contact with the solar cell and cause a short circuit. Also, the lead wiring member may become in contact with the solar cell and damage the solar cell. To address the former concern, the lead wiring member is laminated to insulate the lead wiring member. To address the latter concern, an ethylene-vinyl acetate copolymer (EVA) sheet is inserted as a cushion member between the lead wiring member and the solar cell. These measures cause the structure of the solar cell module including the solar cell panel to become complicated and increases the number of steps to manufacture the solar cell module. To simplify the structure of the solar cell module, the lead wiring member is not laminated and an EVA sheet is not inserted. Instead, the insulation properties and cushioning properties are secured by inserting an insulating member (e.g., an insulating sheet) between the bridge wiring member/solar cell and the lead wiring member.

In the case a terminal box is attached on the back surface side of the solar cell panel, a silicone adhesive is used as described above. More specifically, the back surface of the solar cell panel or the terminal box is coated with a liquid silicone adhesive. The back surface of the solar cell panel and the terminal box are then attached to each other and maintained in that state until the silicone adhesive is solidified. A double-sided adhesive tape is used to bond the back surface of the solar cell panel and the terminal box for temporary attachment of the terminal box until the silicone adhesive is solidified. The thickness of the double-sided adhesive tape creates a gap between the back surface of the solar panel and the terminal box. The gap may cause the terminal box to become shaky. If the terminal box becomes shaky, the silicone adhesive undergoes a stress, with the result that the terminal box may be displaced from the position where it is intended be attached.

The structure of the solar cell module according to the embodiment for inhibiting the shakiness from occurring when the terminal box is bonded by a double-sided adhesive tape is as described below. The peripheral portion of a slit for guiding the lead wiring on the back surface side of the solar cell panel projects farther than the other portion (hereinafter, referred to as “non-peripheral portion”) due to the presence of an insulating sheet. In this embodiment, the back surface of the solar cell panel and the terminal box are bonded by pasting the double-side adhesive tape on the non-peripheral portion. This results in the peripheral portion and the double-sided adhesive tape supporting the terminal box so that the occurrence of shakiness is inhibited. The terms “parallel” and “orthogonal” in the following description not only encompass completely parallel or orthogonal but also encompass slightly off-parallel within the margin of error. The term “substantially” means identical within certain limits. A description will first be given of (1) structure of a solar cell panel and (2) attachment of a terminal box to the solar cell panel.

### (1) Structure of Solar Cell

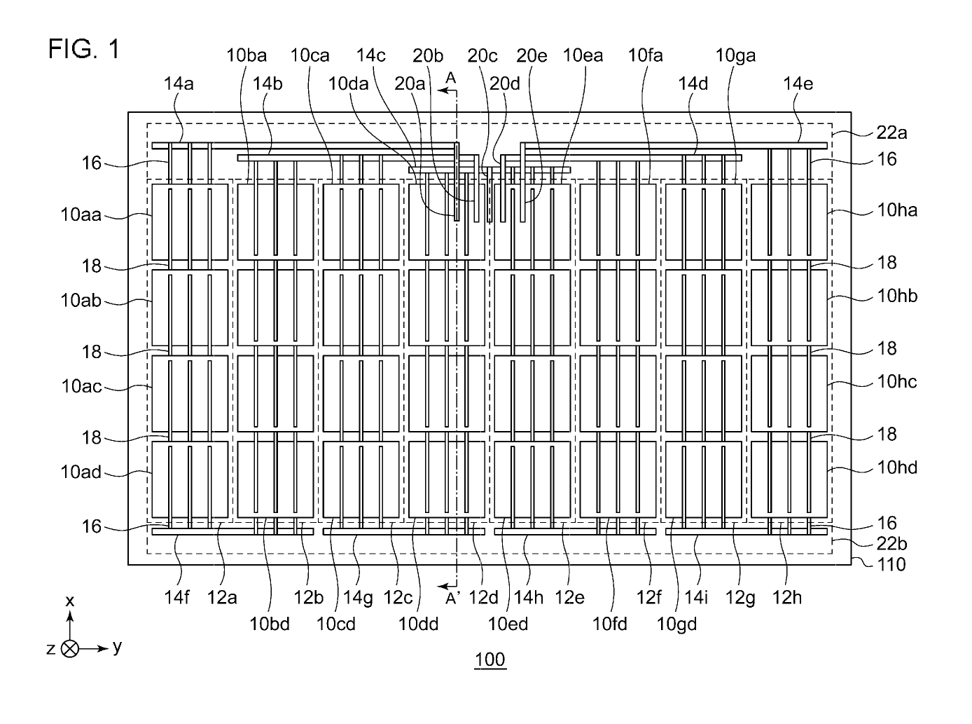

FIG. 1 is a plan view of a solar cell module 100 according to the embodiment as viewed from the back surface side, showing, in particular, a solar cell panel 110 of the solar cell module 100. In the solar cell module 100, a frame is attached to surround the solar cell panel 110, and a terminal box is provided on the back surface side of the solar cell panel 110, but a description of the frame and the terminal box is omitted. As shown in FIG. 1, an orthogonal coordinate system including an x axis, y axis, and a z axis is defined. The x axis and y axis are orthogonal to each other in the plane of the solar cell panel 110. The z axis is perpendicular to the x axis and y axis and extends in the direction of thickness of the solar cell panel 110. The positive directions of the x axis, y axis, and z axis are defined in the directions of arrows in FIG. 1, and the negative directions are defined in the directions opposite to those of the arrows. Of the two principal surfaces forming the solar cell panel 110 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”.

The solar cell panel 110 includes an 11th solar cell 10aa, . . . , an 84th solar cell 10hd, which are generically referred to as solar cells 10, a first bridge wiring member 14a, a second bridge wiring member 14b, a third bridge wiring member 14c, a fourth bridge wiring member 14d, a fifth bridge wiring member 14e, a sixth bridge wiring member 14f, a seventh bridge wiring member 14g, an eighth bridge wiring member 14h, a ninth bridge wiring member 14i, which are generically referred to as bridge wiring members 14, a cell end wiring member 16, an inter-cell wiring member 18, and a first lead wiring member 20a, a second lead wiring member 20b, a third lead wiring member 20c, a fourth lead wiring member 20d, a fifth lead wiring member 20e, which are generically referred to as lead wiring members 20.

The solar cell panel 110 has a rectangular plate shape extending on the x-y plane. A first non-generating area 22a and a second non-generating area 22b are disposed to sandwich the plurality of solar cells 10 in the x axis direction. More specifically, the first non-generating area 22a is disposed farther on the positive direction side along the x axis than the plurality of solar cells 10, and the second non-generating area 22b is disposed further on the the negative direction side along the x axis than the plurality of solar cells 10. The first non-generating area 22a and the second non-generating area 22b (hereinafter, sometimes generically referred to as “non-generating areas 22”) have a rectangular shape and do not include the solar cells 10.

Each of the plurality of solar cells 10 absorbs incident light and generates photovoltaic power. The solar cell 10 is formed of, for example, a semiconductor material such as crystalline silicon, gallium arsenide (GaAs), or indium phosphorus (InP). The structure of the solar cell 10 is not limited to any particular type. It is assumed that crystalline silicon and amorphous silicon are stacked by way of example. A plurality of finger electrodes (not shown in FIG. 1) extending in the y axis direction in a mutually parallel manner and a plurality of (e.g., three) bus bar electrodes extending in the x axis direction to be orthogonal to the plurality of finger electrodes are disposed on the light receiving surface and the back surface of each solar cell 10. The bus bar electrodes connect the plurality of finger electrodes to each other. The bus bar electrodes and the finger electrodes are formed of, for example, silver paste or the like.

The plurality of solar cells 10 are arranged in a matrix on the x-y plane. By way of example, four solar cells 10 are arranged in the x axis direction and eight solar cells 10 are arranged in the y axis direction. The number of solar cells 10 arranged in the x axis direction and the number of solar cells 10 arranged in the y axis direction are not limited to the examples above. The four solar cells 10 arranged and disposed in the x axis direction are connected in series by the inter-cell wiring member 18 so as to form one solar cell string 12. For example, by connecting the 11th solar cell 10aa, a 12th solar cell 10ab, a 13th solar cell 10ac, and a 14th solar cell 10ad, a 1st solar cell string 12a is formed. The other solar cell strings 12 (e.g., a 2nd solar cell string 12b through an 8th solar cell string 12h) are similarly formed. As a result, the eight solar cell strings 12 are arranged in parallel in the y axis direction.

Of these eight solar cell strings 12, one solar cell string 12 (hereinafter, also referred to as a “first solar cell string 12”) extends in the x axis direction. Of the eight solar cell strings 12, another one solar cell string 12 (hereinafter, also referred to as a “second solar cell string 12”) extends along the first solar cell string 12.

Given, for example, that the last solar cell string 12a represents the “first solar cell string 12”, at least one of a 2nd solar cell string 12b through a 4th solar cell string 12d represents the “second solar cell string 12”. Alternatively, given that at least one of the 2nd solar cell string 12b and a 3rd solar cell string 12c represents the “first solar cell string 12”, the 4th solar cell string 12d represents the “second solar cell string 12”.

Alternatively, given that the 8th solar cell string 12h represents the “first solar cell string 12”, at least one of a 5th solar cell string 12e through a 7th solar cell string 12g represents the “second solar cell string 12”. Alternatively, given that at least one of a 6th solar cell string 12f and the 7th solar cell string 12g represents the “first solar cell string 12”, the 5th solar cell string 12e represents the “second solar cell string 12”.

In order to form the solar cell strings 12, the inter-cell wiring members 18 connect the bus bar electrode on the light receiving surface side of one of adjacent solar cells 10 to the bus bar electrode on the back surface side of the other solar cell 10. For example, the three inter-cell wiring members 18 for connecting the 11th solar cell 10aa and the 12th solar cell 10ab electrically connect the bus bar electrode on the back surface side of the 11th solar cell 10aa and the bus bar electrode on the light receiving surface side of the 12th solar cell 10ab.

Five of the nine bridge wiring members 14 are provided in the first non-generating area 22a, and the remaining four are provided in the second non-generating area 22b. Each of the sixth bridge wiring member 14f through the ninth bridge wiring member 14i provided in the second non-generating area 22b extends in the y axis direction and is electrically connected to two adjacent solar cell strings 12 via the cell end wiring member 16. For example, the sixth bridge wiring member 14f is electrically connected to the 14th solar cell 10ad in the 1st solar cell string 12a and the 24th solar cell 10bd in the 2nd solar cell string 12b via the cell end wiring member 16. The cell end wiring member 16 is provided on the light receiving surface or the back surface of the solar cell 10 in a manner similar to that of the inter-cell wiring member 18.

The first bridge wiring member 14a provided in the first non-generating area 22a is connected to the 11th solar cell 10aa at the positive direction end of the 1st solar cell string 12a along the x axis via the cell end wiring member 16. The first bridge wiring member 14a extends from a portion of connection with the cell end wiring member 16 in the positive direction along the y axis as far as the neighborhood of the center of the solar cell panel 110 in the y axis direction. The first lead wiring member 20a extends as a bent extension from the first bridge wiring member 14a in the negative direction in the x axis direction.

The second bridge wiring member 14b is connected to the 21th solar cell 10ba at the positive direction end of the 2nd solar cell string 12b along the x axis via the cell end wiring member 16. Moreover, the second bridge wiring member 14b is also connected to the 31st solar cell 10ca at the positive direction end of the 3rd solar cell string 12c along the x axis via another cell end wiring member 16. Through these connections, the second bridge wiring member 14b electrically connects the 2nd solar cell string 12b and the 3rd solar cell string 12c. Further, the second bridge wiring member 14b extends from a portion of connection with the cell end wiring member 16 in the positive direction along the y axis as far as the neighborhood of the center of the solar cell panel 110 in the y axis direction. In other words, the second bridge wiring member 14b extends along the first bridge wiring member 14a. In particular, the second bridge wiring member 14b is closer to the center of the solar cell panel 110 in the y axis direction than the first bridge wiring member 14a and so extends to intersect the first lead wiring member 20a. The second lead wiring member 20b extends as a bent extension from the second bridge wiring member 14b in the negative direction along the x axis, i.e., extends along the first lead wiring member 20a.

The third bridge wiring member 14c is connected to the 41th solar cell 10da at the positive direction end of the 4th solar cell string 12d along the x axis via the cell end wiring member 16. Moreover, the third bridge wiring member 14c is also connected to the 51st solar cell 10ea at the positive direction end of the 5th solar cell string 12e in the x axis direction via another cell end wiring member 16. Through these connections, the third bridge wiring member 14c electrically connects the 4th solar cell string 12d and the 5th solar cell string 12e. The third bridge wiring member 14c configured as described above extends in the y axis direction across the center of the solar cell panel 110 in the y axis direction. In other words, the third bridge wiring member 14c extends along the first bridge wiring member 14a and extends to intersect the first lead wiring member 20a and the second lead wiring member 20b. The third lead wiring member 20c extends from the central portion of the second bridge wiring member 14b in the negative direction along the x axis, i.e., extends along the first lead wiring member 20a or the second lead wiring member 20b.

The the fourth bridge wiring member 14d and the fourth lead wiring member 20d are in a mirror arrangement with respect to the second bridge wiring member 14b and the second lead wiring member 20b in the y axis direction. Moreover, the fifth bridge wiring member 14e and the fifth lead wiring member 20e are in a mirror arrangement with respect to the first bridge wiring member 14a and the first lead wiring member 20a in the y axis direction. Therefore, the 1st solar cell string 12a through the 8th solar cell string 12h are electrically connected in series, and the first lead wiring member 20a through the fifth lead wiring member 20e are arranged and disposed in the y axis direction and are connected to the terminal box (not shown).

In this configuration, the bridge wiring member 14 and the lead wiring member 20 connected to the first solar cell string 12 are called a “first bridge wiring member 14” and a “first lead wiring member 20”, respectively. Moreover, the bridge wiring member 14 and the lead wiring member 20 connected to the second solar cell string 12 are called a “second bridge wiring member 14” and a “second lead wiring member 20”, respectively. Given, for example, that the 1st solar cell string 12a represents the “first solar cell string 12”, the first bridge wiring member 14a and the first lead wiring member 20a represent the “first bridge wiring member 14” and the “first lead wiring member 20”, respectively. In this case, at least one of the second bridge wiring member 14b and the third bridge wiring member 14c represents the “second bridge wiring member 14”, and at least one of the second lead wiring member 20b and the third lead wiring member 20c connected to the “second bridge wiring member 14” represents the “second lead wiring member 20”.

Given, for example, that at least one of the 2nd solar cell string 12b and the 3rd solar cell string 12c represents the “first solar cell string 12”, the second bridge wiring member 14b and the second lead wiring member 20b represent the “first bridge wiring member 14” and the “first lead wiring member 20”, respectively. In this case, the third bridge wiring member 14c and the third lead wiring member 20c represent the “second bridge wiring member 14” and the “second lead wiring member 20”, respectively. The third bridge wiring member 14c through the fifth bridge wiring member 14e are similarly defined as the “first bridge wiring member 14” or the “second bridge wiring member 14”. The third lead wiring member 20c through the fifth lead wiring member 20e are similarly defined as the “first lead wiring member 20” or the “second lead wiring member 20”.

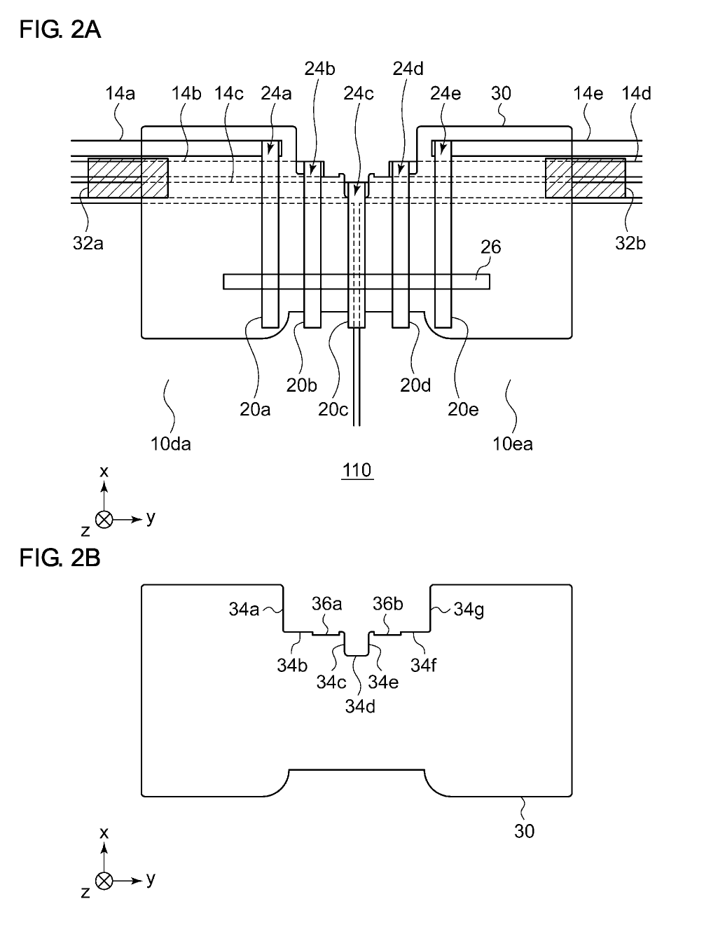

FIGS. 2A-2A are enlarged plan views of a portion of the solar cell panel 110. In particular, FIG. 2A is an enlarged plan view of the central portion of the solar cell panel 110 of FIG. 1 in the y axis direction, i.e., an enlarged plan view of the portion in which the first lead wiring member 20a through the fifth lead wiring member 20e are provided. The first bridge wiring member 14a through the fifth bridge wiring member 14e, and the first lead wiring member 20a through the fifth lead wiring member 20e are provided in a manner similar to that of FIG. 1. At least the first lead wiring member 20a through the fifth lead wiring member 20e are not laminated or coated. Further, the figures show a first connection point 24a through a fifth connection point 24e. At the first connection point 24a, the first bridge wiring member 14a and the first lead wiring member 20a intersect each other and are electrically connected. The same is true of a second connection point 24b through the fifth connection point 24e.

An insulating member 30, which is omitted from the illustration in FIG. 1, is provided in the portion where the first lead wiring member 20a through the fifth lead wiring member 20e are provided. The insulating member 30 has a multilayer structure in which EVA, polyethylene terephthalate (PET), and EVA are stacked successively in the z axis direction and represents the insulating sheet described above. It should be noted that the melting point of EVA is about 70˜80° C., and the melting point of PET is about 260° C. Meanwhile, the temperature at which the solar cell panel 110 is laminated is about 150° C. In other words, PET, which forms the insulating member 30, has a melting point higher than the temperature at which the solar cell panel 110 is laminated. Therefore, the insulating member 30 remains unmelted even after the laminated solar cell panel 110 is manufactured. FIG. 2B will be used to explain the shape of the insulating member 30.

FIG. 2B shows the structure of the insulating member 30 and shows an appearance similar to that of FIG. 2A. The insulating member 30 has a rectangular shape more elongated in the y axis direction than in the x axis direction on the x-y plane. The two edges extending in the y axis direction are shaped to recede near the center. In particular, the edge of the insulating member 30 at the positive direction end along the x axis is shaped to recede in steps formed by a first edge 34a through a seventh edge 34g. To describe it more specifically, the first edge 34a extending in the x axis direction, a second edge 34b and a sixth edge 34f extending in the y axis direction, and the seventh edge 34g extending in the x axis direction form a recess on the first level. Moreover, a third edge 34c extending in the x axis direction, a fourth edge 34d extending in the y axis direction, and a fifth edge 34e extending in the x axis direction form a recess on the second level near the center of the recess on the first level. Further, a first groove 36a is formed in the second edge 34b, and a second groove 36b is formed in the sixth edge 34f. Reference is made back to FIG. 2A.

The first bridge wiring member 14a, the first connection point 24a, the first lead wiring member 20a, the fifth bridge wiring member 14e, the fifth connection point 24e, and the fifth lead wiring member 20e are provided on the surface of the insulating member 30 on the negative direction side along the z axis. Further, the second bridge wiring member 14b through the fourth bridge wiring member 14d are provided on the surface of the insulating member 30 on the positive direction side along the z axis, and the second lead wiring member 20b through the fourth lead wiring member 20d are provided on the surface of the insulating member 30 on the negative direction side along the z axis. Further, the second connection point 24b through the fourth connection point 24d are provided neither on the surface of the insulating member 30 on the positive direction side along the z axis nor on the surface on the negative direction side. In other words, the insulating member 30 causes the first lead wiring member 20 and the second bridge wiring member 14 to be provided on different surfaces.

It is thus ensured that the second bridge wiring member 14b or the third bridge wiring member 14c, and the first lead wiring member 20a are provided to sandwich the insulating member 30 in the z axis direction in the portion in which the second bridge wiring member 14b or the third bridge wiring member 14c intersects the first lead wiring member 20a. Moreover, the second lead wiring member 20b or the fourth lead wiring member 20d, and the third bridge wiring member 14c are provided to sandwich the insulating member 30 in the z axis direction in the portion in which the second lead wiring member 20b or the fourth lead wiring member 20d intersects the third bridge wiring member 14c. As a result, the first lead wiring member 20 and the second bridge wiring member 14 are insulated from each other by the insulating member 30 in the portion of intersection as well. Further, the insulating member 30 causes the 41th solar cell 10da and the 51st solar cell 10ea to be provided on the surface different from the surface on which the first lead wiring member 20a through the fifth lead wiring member 20e are provided. Therefore, the insulating member 30 also provides insulation of the first lead wiring member 20a through the fifth lead wiring member 20e from the 41st solar cell 10da and the 51st solar cell 10ea.

A first fixing member 32a and a second fixing member 32b have a rectangular shape on the x-y plane. An adhesive is provided on the surface of the first fixing member 32a and the second fixing member 32b on the positive direction side along the z axis. The first fixing member 32a and the second fixing member 32b are embodied by, for example, a tape. The first fixing member 32a fixes the second bridge wiring member 14b, the third bridge wiring member 14c, and the 41st solar cell 10da together. Moreover, the second fixing member 32b fixes the third bridge wiring member 14c, the fourth bridge wiring member 14d, and the 51st solar cell 10ea together. A slit 26 is provided on the negative direction side of the insulating member 30 along the z axis and the first lead wiring member 20a through the fifth lead wiring member 20e are guided outside via the slit 26. The slit 26 on the insulating member 30 increases the creepage distance from the slit 26 to the solar cell 10 and so improves the insulating properties.

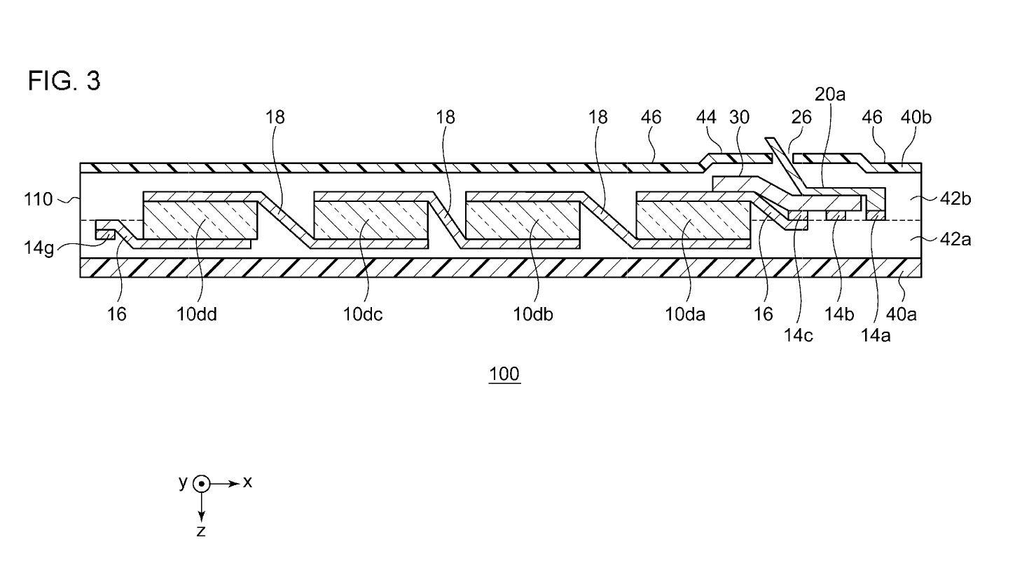

FIG. 3 is a cross sectional view of the solar cell module 100 and is an A-A cross sectional view of FIG. 1. The solar cell panel 110 includes the 41st solar cell 10da, a 42nd solar cell 10db, a 43rd solar cell 10dc, a 44th solar cell 10dd, which are generically referred to as solar cells 10, the first bridge wiring member 14a, the second bridge wiring member 14b, the third bridge wiring member 14c, which are generically referred to as bridge wiring members 14, the cell end wiring member 16, the inter-cell wiring member 18, the first lead wiring member 20a, the slit 26, the insulating member 30, a first protective member 40a, a second protective member 40b, which are generically referred to as protective members 40, and a first encapsulant 42a, a second encapsulant 42b, which are generically referred to as encapsulants 42. The bottom of FIG. 3 corresponds to the light receiving surface, and the top corresponds to the back surface.

The first protective member 40a is disposed on the light receiving surface side of the solar cell panel 110 and protects the surface of the solar cell panel 110. The first protective member 40a is formed by using a translucent and water shielding glass, translucent plastic, etc. and is formed in a rectangular shape. In this case, it is assumed that glass is used. The first encapsulant 42a is stacked on the back surface of the first protective member 40a. The first encapsulant 42a is disposed between the first protective member 40a and the solar cell 10 and adhesively bonds the first protective member 40a and the solar cell 10. For example, a thermoplastic resin sheet of polyolefin, EVA, polyvinyl butyral (PVB), polyimide, or the like may be used as the first encapsulant 42a. A thermosetting resin may alternatively be used. The first encapsulant 42a is formed by a translucent, rectangular sheet member having a surface of substantially the same dimension as the x-y plane in the first protective member 40a.

The second encapsulant 42b is stacked on the back surface side of the first encapsulant 42a. The second encapsulant 42b encapsulates the plurality of solar cells 10, the inter-cell wiring members 18, etc. between the second encapsulant 42b and the first encapsulant 42a. The second encapsulant 42b may be formed of a material similar to that of the first encapsulant 42a. Alternatively, the second encapsulant 42b may be integrated with the first encapsulant 42a by heating the members in a laminate cure process.

The second protective member 40b is stacked on the back surface side of the second encapsulant 42b. The second protective member 40b protects the back surface side of the solar cell panel 110 as a back sheet. A resin (e.g., PET) film is used for the second protective member 40b. A stack film having a structure in which an Al foil is sandwiched by resin films, or the like is used as the second protective member 40b.

The third bridge wiring member 14c, the second bridge wiring member 14b, and the first bridge wiring member 14a are arranged and disposed in the positive direction along the x axis, and the insulating member 30 is provided on the negative direction side of the third bridge wiring member 14c and the second bridge wiring member 14b along the z axis. The cell end wiring member 16 from the 41st solar cell 10da is connected to the third bridge wiring member 14c, and the first lead wiring member 20a is connected to the first bridge wiring member 14a. The first lead wiring member 20a extends to intersect the second bridge wiring member 14b and the third bridge wiring member 14c, sandwiching the insulating member 30 in the z axis direction and is exposed outside the via the slit 26 provided in the second protective member 40b. As described above, the terminal box (not shown) is connected to the first lead wiring member 20a exposed outside via the slit 26. An Al frame may be attached to the circumference of the solar cell panel 110.

Since a resin (e.g., PET) film is used for the second protective member 40b as described above, the second protective member 40b projects farther toward the negative direction side along the z axis in the portion where the insulating member 30 is provided than in the portion where the insulating member 30 is not provided. The portion of the second protective member 40b projecting toward the negative direction side along the z axis as a result of providing the insulating member 30 is indicated in the figure as a peripheral portion 44, and the portion other than the peripheral portion 44 is indicated as a non-peripheral portion 46. The height of the projection of the peripheral portion 44 in the z axis direction relative to the non-peripheral portion 46 is equivalent to the thickness of the insulating member 30 in the z axis direction.

It has been assumed so far that five bridge wiring members 14 and five lead wiring members 20 are provided as a result of providing eight solar cell strings 12 in the solar cell panel 110. Alternatively, four bridge wiring members 14 and four lead wiring members 20 may be provided as a result of providing six solar cell strings 12 in the solar cell panel 110. The insulating member 30 in this case has a shape similar to the one described above. A description will now be given of the alternative arrangement.

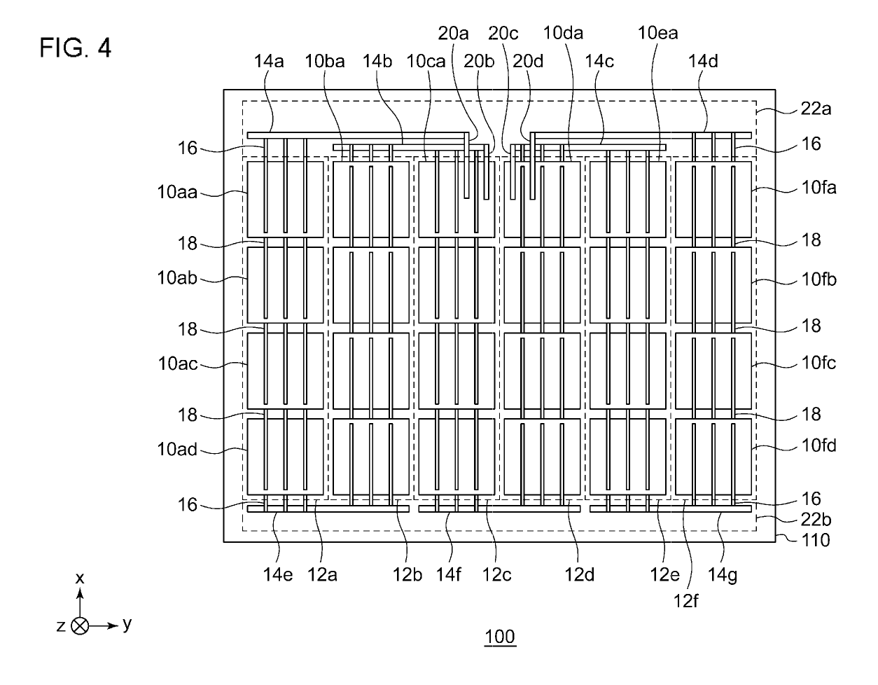

FIG. 4 is a plan view of another solar cell module 100 according to the embodiment as viewed from the back surface side. The appearance is similar to that of FIG. 1. Given, for example, that the 1st solar cell string 12a represents the “first solar cell string 12”, at least one of the 2nd solar cell string 12b and the 3rd solar cell string 12c represents the “second solar cell string 12”. Alternatively, given that the 6th solar cell string 12f represents the “first solar cell string 12”, at least one of the 4th solar cell string 12d and the 5th solar cell string 12e represents the “second solar cell string 12”.

The second bridge wiring member 14b is closer to the center of the solar cell panel 110 in the y axis direction than the first bridge wiring member 14a and so extends to intersect the first lead wiring member 20a. The the third bridge wiring member 14c and the third lead wiring member 20c are in a mirror arrangement with respect to the second bridge wiring member 14b and the second lead wiring member 20b in the y axis direction. Moreover, the fourth bridge wiring member 14d and the fourth lead wiring member 20d are in a mirror arrangement with respect to the first bridge wiring member 14a and the first lead wiring member 20a in the y axis direction.

The first bridge wiring member 14a and the first lead wiring member 20a represent the “first bridge wiring member 14” and the “first lead wiring member 20”, respectively, and the second bridge wiring member 14b and the second lead wiring member 20b represent the “second bridge wiring member 14” and the “second lead wiring member 20”, respectively. Moreover, the fourth bridge wiring member 14d and the fourth lead wiring member 20d represent the “first bridge wiring member 14” and the “first lead wiring member 20”, and the third bridge wiring member 14c and the third lead wiring member 20c represent the “second bridge wiring member 14” and the “second lead wiring member 20”, respectively.

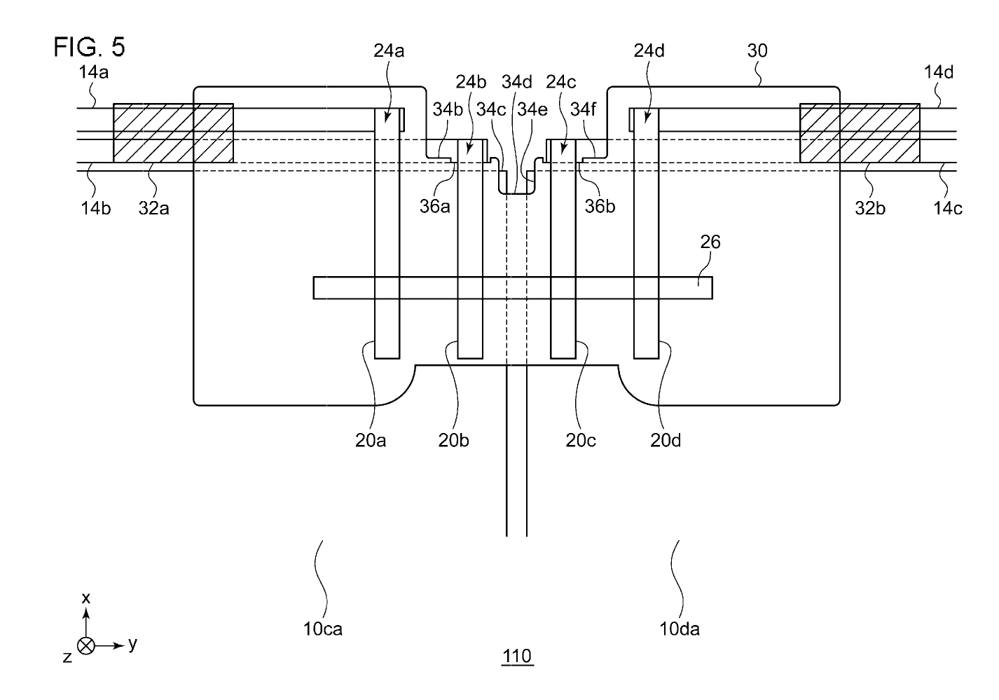

FIG. 5 is an enlarged plan view of a portion of the solar cell panel 110. The appearance in FIG. 5 is similar to that of FIG. 2A. The first bridge wiring member 14a through the fourth bridge wiring member 14d, and the first lead wiring member 20a through the fourth lead wiring member 20d are provided in a manner similar to that of FIG. 4. The first bridge wiring member 14a, the first connection point 24a, the first lead wiring member 20a, the fourth bridge wiring member 14d, the fourth connection point 24d, and the fourth lead wiring member 20d are provided on the surface of the insulating member 30 on the negative direction side along the z axis. The second bridge wiring member 14b and the third bridge wiring member 14c are provided on the surface of the insulating member 30 on the positive direction side along the z axis, and the second lead wiring member 20b and the third lead wiring member 20c are provided on the surface of the insulating member 30 on the negative direction side along the z axis. Further, the second connection point 24b and the third connection point 24c are provided neither on the surface of the insulating member 30 on the positive direction side along the z axis nor on the surface on the negative direction side.

In other words, the insulating member 30 causes the first lead wiring member 20 and the second bridge wiring member 14 to be provided on different surfaces. It is thus ensured that the second bridge wiring member 14b and the first lead wiring member 20a are provided to sandwich the insulating member 30 in the z axis direction in the portion in which the second bridge wiring member 14b intersects the first lead wiring member 20a. The third bridge wiring member 14c and the fourth lead wiring member 20d are also provided to sandwich the insulating member 30 in the z axis direction in the portion in which the third bridge wiring member 14c intersects the fourth lead wiring member 20d.

Since both the number of the bridge wiring members 14 and number of the lead wiring members 20 are “4”, no bridge wiring members 14 or the lead wiring members 20 are provided in the recess on the second level formed by the third edge 34c, the fourth edge 34d, and the fifth edge 34e in the insulating member 30. Further, the second edge 34b of the insulating member 30 that is in contact with the second lead wiring member 20b extending from the second connection point 24b includes the first groove 36a capable of sandwiching the second lead wiring member 20b. Moreover, the sixth edge 34f of the insulating member 30 that is in contact with the third lead wiring member 20c extending from the third connection point 24c includes the second groove 36b capable of sandwiching the third lead wiring member 20c.

The first fixing member 32a fixes the first bridge wiring member 14a, the second bridge wiring member 14b, and the 31st solar cell 10ca together. Moreover, the second fixing member 32b fixes the third bridge wiring member 14c, the fourth bridge wiring member 14d, and the 41st solar cell 10da together. A slit 26 is provided on the negative direction side of the insulating member 30 along the z axis and the first lead wiring member 20a through the fourth lead wiring member 20d are guided outside via the slit 26.

### (2) Attachment of a Terminal Box to the Solar Cell Panel

The structure in which the terminal box is attached to the solar cell panel 110 will be described below. It is assumed that the number of the bridge wiring members 14 and the lead wiring members 20 in the solar cell panel 110 is “5”. The description below also applies to the structure where the number of the bridge wiring members 14 and the lead wiring members 20 is “4”.

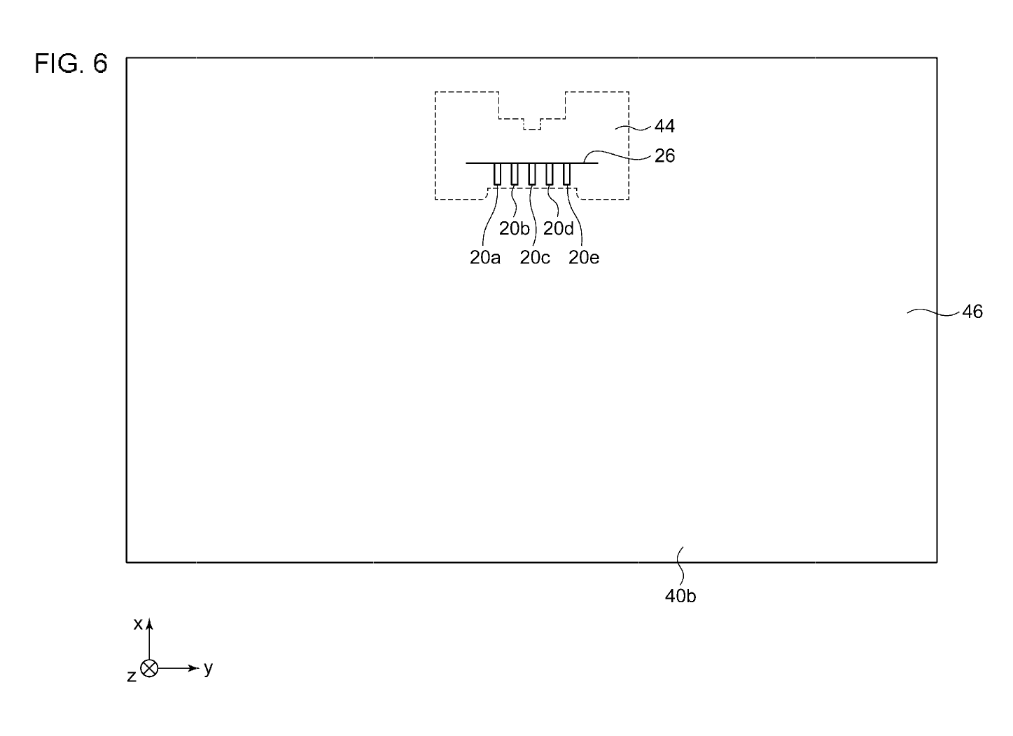

FIG. 6 is a plan view of the second protective member 40b as viewed from the back surface side, showing a structure more toward the negative direction side along the z axis than the appearance shown in FIG. 1. The second protective member 40b includes the peripheral portion 44, the non-peripheral portion 46, and the slit 26. The second protective member 40b includes the slit 26 that exposes the lead wiring member 20 from the solar cell panel 110. The figure shows that the first lead wiring member 20a through the fifth lead wiring member 20e are guided through the slit 26. The positions of the first lead wiring member 20a through the fifth lead wiring member 20e shown in FIG. 6 correspond to the positions thereof in FIG. 1.

The peripheral portion 44 is formed around the slit 26. The non-peripheral portion 46 is provided in the portion other than the peripheral portion 44 so as to surround the peripheral portion 44. As described above, the peripheral portion 44 is a portion where the second protective member 40b projects toward the negative direction side along the z axis as a result of providing the insulating member 30 within the solar cell panel 110. Therefore, the shape of the peripheral portion 44 on the x-y plane is similar to the shape of the insulating member 30 shown in FIGS. 2A-2B. In the non-peripheral portion 46, on the other hand, the insulating member 30 is not provided within the solar cell panel 110. Therefore, the peripheral portion 44 projects farther than the non-peripheral portion 46.

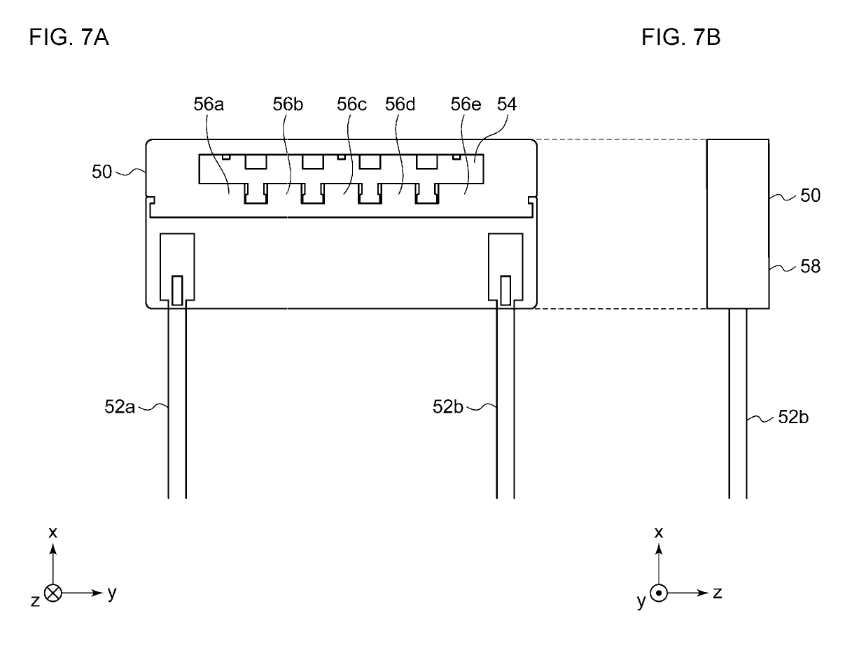

FIGS. 7A-7B show a structure of a terminal box 50 attached to the solar cell module 100. FIG. 7A is a plan view of the terminal box 50 as viewed from the back surface side, and FIG. 7B is a side view of the terminal box 50. The terminal box 50 includes a hollow portion 54, a first mount 56a, a second mount 56b, a third mount 56c, a fourth mount 56d, a fifth mount 56e, which are generically referred to as mounts 56, and a planar part 58. The terminal box 50 is configured to have a box shape and the hollow portion 54 having a hollow structure is provided inside the box. The first mount 56a through the fifth mount 56e are provided in the hollow portion 54. The first lead wiring member 20a through the fifth lead wiring member 20e (not shown) can be connected to the first mount 56a through the fifth mount 56e, respectively, with a solder. The mounts 56 may include a plurality of bypass diodes (not shown). The mounts 56 are electrically connected to a first cable 52a and a second cable 52b. Moreover, the planar part 58 is provided on the positive direction side of the terminal box 50 along the z axis. A publicly known technology may be used to configure the terminal box 50.

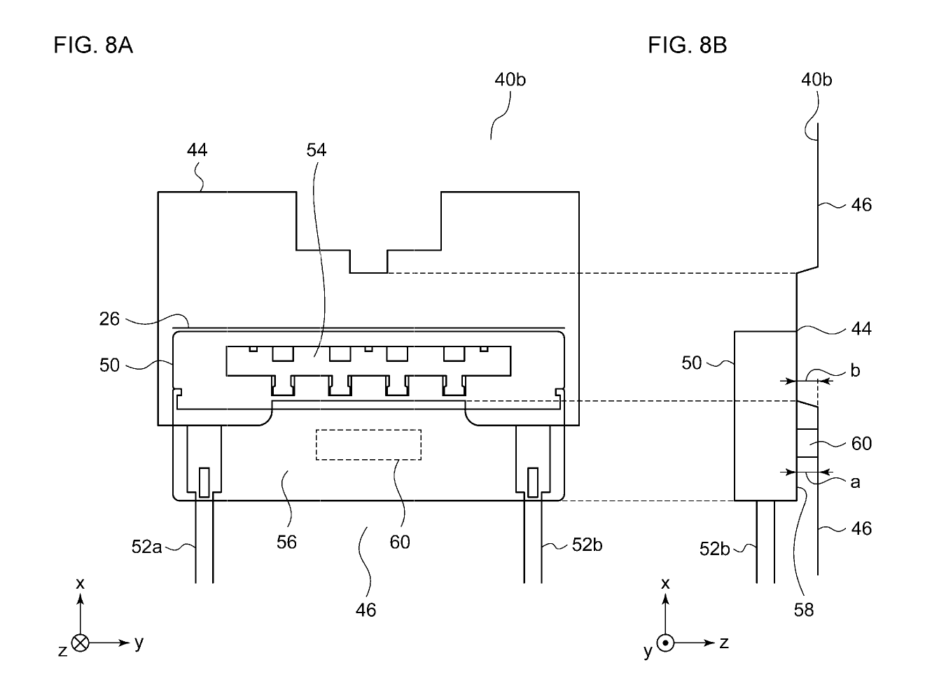

FIG. 8A-8b show a structure of the solar cell module 100 in which the terminal box 50 is attached. The figures show a portion near the peripheral portion 44 in FIG. 6 and the appearance shown in FIGS. 7A-7B. As shown in FIG. 8A, the peripheral portion 44 having a shape similar to the shape of the insulating member 30 is provided in the second protective member 40b, and the non-peripheral portion 46 is provided around the peripheral portion 44. Moreover, as shown in FIG. 8B, the peripheral portion 44 projects farther toward the negative direction side along the z axis than the non-peripheral portion 46.

The terminal box 50 is attached across the peripheral portion 44 and the non-peripheral portion 46 in the second protective member 40b. A silicone adhesive is applied to the portion where the terminal box 50 and the second protective member 40b face. Since the silicone adhesive as applied is liquid, it is necessary to temporarily attach the terminal box 50 to the second protective member 40b until the silicone adhesive is solidified. In this case, a bonding member 60 is used for temporary attachment. For example, the bonding member 60 is a double-sided adhesive tape. The bonding member 60 is provided in the non-peripheral portion 46 in the second protective member 40b and bonds the non-peripheral portion 46 and the planar part 58 of the terminal box 50 that faces the non-peripheral portion 46.

The bonding member 60 has a height “a” in the z axis direction. Meanwhile, the peripheral portion 44 has a height “b” from the non-peripheral portion 46 in the z axis direction. The planar part 58 of the terminal box 50 is supported by the bonding member 60 and the peripheral portion 44 from the positive direction side along the z axis. The closer the height “a” and the height “b” to each other, the more successfully the shakiness of the terminal box 50 temporarily attached is inhibited.

A description will now be given of a method of manufacturing the solar cell module 100. A description will be given of (i) manufacturing of the solar cell panel 110 and (ii) attachment of a terminal box 50 to the solar cell panel 110 in the stated order.

### (1) Manufacturing of the Solar Cell Panel 110

First, the stack is produced by sequentially layering the first protective member 40a, the first encapsulant 42a, the solar cell 10, the insulating member 30, the second encapsulant 42b, and the second protective member 40b from the positive direction side toward the negative direction side along the z axis. This is followed by a laminate cure process performed for the stack. In this process, air is drawn from the stack, and the stack is heated and pressurized so as to be integrated. In vacuum lamination in the laminate cure process, the temperature is set to about 50˜150°, as mentioned before.

### (2) Attachment of the Terminal Box 50 to the Solar Cell Panel 110

The planar part 58 of the terminal box 50 or the portion across the peripheral portion 44 and the non-peripheral portion 46 is coated with a silicone adhesive. Subsequently, the bonding member 60 is attached to the planar part 58 of the terminal box 50 or the non-peripheral portion 46. The planar part 58 of the terminal box 50 and the second protective member 40b are bonded in this state. Bonding here represents temporary attachment by the bonding member 60, and the state is maintained until the silicone adhesive is solidified.

According to the embodiment, the bonding member 60 is provided in the non-peripheral portion 46 in the second protective member 40b to bond the second protective member 40b and the terminal box 50. Therefore, the terminal box 50 is supported by the bonding member 60 and the peripheral portion 44. Moreover, the terminal box 50 is supported by the bonding member 60 and the peripheral portion 44 so that the shakiness of the terminal box 50 is inhibited. Moreover, the shakiness of the terminal box 50 is inhibited so that the silicone adhesive is allowed to be solidified while the relative positions of the terminal box 50 and the second protective member 40b remain fixed. Moreover, the bonding member 60 is provided in the non-peripheral portion 46 in the second protective member 40b so that the height of the bonding member 60 is approximated to the height of the peripheral portion 44. Moreover, in the peripheral portion 44, the insulating member 30 is provided within the solar cell panel 110 and, in the non-peripheral portion 46, is not provided within the solar cell panel 110 so that the insulating member 30 makes the peripheral portion 44 higher than the non-peripheral portion 46.

Since the insulating member 30 causes the first lead wiring member 20 and the second bridge wiring member 14 to be provided on different surfaces, the first lead wiring member 20 and the second bridge wiring member 14 are insulated from each other. Moreover, insulation of the first lead wiring member 20 from the second bridge wiring member 14 by the insulating member 30 makes it unnecessary to laminate the lead wiring member 20. Moreover, the insulating member 30 has a melting point higher than the temperature at which the solar cell panel 110 is laminated so that the first lead wiring member 20 and the second bridge wiring member 14 are insulated even after the lamination. Moreover, the insulating member 30 is formed by a stack structure of EVA, PET, and EVA so that the cushion properties are secured. Moreover, it is only required to insert the insulating member 30 so that the structure of the solar cell module 100 is simplified. Moreover, the structure of the solar cell module 100 is simplified so that the manufacturing process is prevented from becoming complicated.

Moreover, the insulating member 30 causes the first lead wiring member 20 and the first bridge wiring member 14 to be provided on different surfaces and causes the connection point 24 therebetween not to be provided on the surfaces so that the first lead wiring member 20 is guided outside, while also insulating the first lead wiring member 20 and the second bridge wiring member 14. Moreover, the insulating member 30 causes the second lead wiring member 20 and the second bridge wiring member 14 to be provided on different surfaces and causes the connection point 24 therebetween not to be provided on the surfaces so that the second lead wiring member 20 is guided outside, while also insulating the first lead wiring member 20 and the second bridge wiring member 14. Moreover, the insulating member 30 includes the recess on the first level and the recess on the second level so that the insulating member 30 can be used regardless of whether the number of the bridge wiring members 14 and the lead wiring members 20 is “4” or “5”. Moreover, the insulating member 30 includes the groove 36 so that the second lead wiring member 20 is fixed in a reinforced manner. Since the slit 26 is provided on the insulating member 30, the creepage distance is extended. Moreover, the fixing member 32 fixes the first bridge wiring member 14, the second bridge wiring member 14, and the insulating member 30 together so that the amount of the fixing member 32 used is reduced.

A summary of the embodiment is given below. A solar cell module 100 according to an embodiment of the disclosure includes a second protective member 40b including a slit 26 for exposing a lead wiring member 20 from a solar cell panel 110, a terminal box 50 connected to a lead wiring member 20 from the slit 26 in the second protective member 40b, and a bonding member 60 that bonds the terminal box 50 and the second protective member 40b. A peripheral portion 44 around the slit 26 in the second protective member 40b projects farther than a non-peripheral portion 46 other than the peripheral portion 44, and the bonding member 60 is provided in the non-peripheral portion 46 in the second protective member 40b.

In the peripheral portion 44 around the slit 26, an insulating member 30 for insulating the lead wiring member 20 may be provided within the solar cell panel 110, and, in the non-peripheral portion 46, the insulating member 30 for the lead wiring member 20 may not be provided within the solar cell panel 110.

Another embodiment of the disclosure relates to a method of manufacturing the solar cell module 100. The method includes attaching a bonding member 60 to a second protective member 40b having a slit 26 for exposing a lead wiring member 20 from a solar cell panel 110 or to a terminal box 50; and bonding the terminal box 50 to the second protective member 40b by the bonding member 60, wherein a peripheral portion 44 around the slit 26 in the second protective member 40b projects farther than a non-peripheral portion 46 other than the peripheral portion 44, and the bonding member 60 is provided in the non-peripheral portion 46 in the second protective member 40b.

Described above is an explanation based on an exemplary embodiment. The embodiment is intended to be illustrative only and it will be understood by those skilled in the art that various modifications to constituting elements and processes could be developed and that such modifications are also within the scope of the present disclosure.

In the embodiment, the insulating member 30 has the same shape regardless of whether the number of the bridge wiring members 14 and the lead wiring members 20 is “4” or “5”. Alternatively, the insulating member 30 may be shaped not to include the recess on the second level when the number of the bridge wiring members 14 and the lead wiring members 20 is “4” According to this variation, the flexibility in the configuration can be improved.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a back surface protective member having a slit for exposing a lead wiring member from a solar cell panel;
a terminal box connected to the lead wiring member from the slit in the back surface protective member; and
a bonding member that bonds the terminal box and the back surface protective member, wherein
a peripheral portion around the slit in the back surface protective member projects farther than a non-peripheral portion other than the peripheral portion, and
the bonding member is provided in the non-peripheral portion in the back surface protective member.

2. The solar cell module according to claim 1, wherein
in the peripheral portion around the slit, an insulating member for insulating the lead wiring member is provided within the solar cell panel, and
in the non-peripheral portion, the insulating member for the lead wiring member is not provided within the solar cell panel.

3. A method of manufacturing a solar cell module comprising:
attaching a bonding member to a back surface protective member having a slit for exposing a lead wiring member from a solar cell panel or to a terminal box; and
bonding the terminal box to the back surface protective member by the bonding member, wherein
a peripheral portion around the slit in the back surface protective member projects farther than a non-peripheral portion other than the peripheral portion, and the bonding member is provided in the non-peripheral portion in the back surface protective member.

4. A solar cell module comprising:
a first solar cell string;
a first bridge wiring member that extends from an end of the first solar cell string in a direction different from a direction in which the first solar cell string extends;
a first lead wiring member that extends in a direction different from the direction in which the first bridge wiring member extends;
a second solar cell string that extends along the first solar cell string;
a second bridge wiring member that extends from an end of the second solar cell string along the first bridge wiring member to intersect the first lead wiring member;
a second lead wiring member that extends from the second bridge wiring member along the first lead wiring member; and
an insulating member that causes the first lead wiring member and the second bridge wiring member to be provided on different surfaces, wherein
at least a portion of the insulating member has a melting point higher than a temperature at which the solar cell module is laminated.

5. The solar cell module according to claim 4, wherein
the insulating member is shaped such that the first lead wiring member and the first bridge wiring member are provided on different surfaces of the insulating member and a point of connection between the first bridge wiring member and the first lead wiring member is not provided on the surfaces of the insulating member.

6. The solar cell module according to claim 4, wherein
the insulating member is shaped such that the second lead wiring member and the second bridge wiring member are provided on different surfaces of the insulating member and a point of connection between the second bridge wiring member and the second lead wiring member is not provided on the surfaces of the insulating member.

7. The solar cell module according to claim 4, wherein
solar cells included in the second solar cell string are provided on a surface of the insulating member different from a surface on which the first lead wiring member and the second lead wiring member are provided.

8. The solar cell module according to claim 5, wherein
solar cells included in the second solar cell string are provided on a surface of the insulating member different from a surface on which the first lead wiring member and the second lead wiring member are provided.

9. The solar cell module according to claim 6, wherein
solar cells included in the second solar cell string are provided on a surface of the insulating member different from a surface on which the first lead wiring member and the second lead wiring member are provided.

10. The solar cell module according to claim 6, wherein
an edge of the insulating member that is in contact with the second lead wiring member extending from the point of connection includes a groove capable of sandwiching the second lead wiring member.

11. The solar cell module according to claim 4, further comprising:
a protective member that causes the first lead wiring member and the second lead wiring member to be provided between the protective member and the insulating member, and
the protective member includes, above the insulating member, a slit for leading the first lead wiring member and the second lead wiring member outside.

12. The solar cell module according to claim 4, further comprising:
a fixing member that fixes the first bridge wiring member, the second bridge wiring member, and the insulating member together.

13. The solar cell module according to claim 4, further comprising:
a back surface protective member having a slit for exposing a lead wiring member from a solar cell panel;
a terminal box connected to the lead wiring member from the slit in the back surface protective member; and
a bonding member that bonds the terminal box and the back surface protective member, wherein
a peripheral portion around the slit in the back surface protective member projects farther than a non-peripheral portion other than the peripheral portion, and
the bonding member is provided in the non-peripheral portion in the back surface protective member.

14. The solar cell module according to claim 13, wherein
in the peripheral portion around the slit, an insulating member for insulating the lead wiring member is provided within the solar cell panel, and
in the non-peripheral portion, the insulating member for the lead wiring member is not provided within the solar cell panel.
